(19) United States
(12) Patent Application Publication
(10) Pub. No.: US 2024/0038912 A1
(43) Pub. Date: Feb. 1, 2024

(54) Composition of Transparent Conductive Material and Method for Fabricating the same

(71) Applicant: THE UNIVERSITY OF LIVERPOOL, Liverpool, Merseyside (GB)

(72) Inventors: Jessica STONER, LIVERPOOL (GB); Jonathon ALARIA, LIVERPOOL (GB); Matthew ROSSEINSKY, LIVERPOOL (GB)

(21) Appl. No.: 18/254,861

(22) PCT Filed: Nov. 30, 2021
(86) PCT No.: PCT/GB2021/053121

§ 371 Date: May 28, 2023

(30) Foreign Application Priority Data
Nov. 30, 2020 (GB) 2018825.6

(51) Int. Cl. H01L 31/0224; H01L 33/42; H01L 31/18; C23C 14/08

(52) U.S. Cl. CPC H01L 31/022466; H01L 33/42; H01L 31/1884; C23C 14/086; H01L 2933/0016

(57) ABSTRACT

A film comprising a set of layers including a first layer, a third layer and a second layer therebetween is described. The first layer comprises and/or is a transparent conductive oxide, TCO, having a formula: A¹B¹O_{3-δ1}; The third layer comprises and/or is a transparent wide-bandgap semiconductor oxide having a formula: A³B³0_{3-δ3}; The second layer comprises and/or is an oxide layer having a formula: A¹_{α}A³_{1-α}B¹O_{3-δ2} or A¹_{α}A³_{1-α}B³O_{3-δ2} or A³B¹_{β}B³_{1-β}O_{3-δ2} or A¹_{α}A³_{1-α}B¹_{β}B³_{1-β}O_{3-δ2}; wherein 0<α, β<1, −0.5≤δ₁, δ₂, δ₃≤0.5.

### FIELD

The present invention relates to transparent conducting materials.

### BACKGROUND TO THE INVENTION

Oxide interfaces have shown a wealth of emergent phenomena, presenting remarkable physics beyond conventional semiconductors. Electronic reconstruction at a carefully engineered interface and confined polarisation, spin, and orbital degrees of freedom can lead to properties not observed in the isolated bulk materials. Notable examples include the combination of LaMnO₃ and SrMnO₃, both antiferromagnetic insulators, exhibiting double-exchange ferromagnetism at their interface, and the quantum hall effect in a high-mobility electron gas between ZnO and Zn₁₋ₓMgₓO. A further key example is the LaAlO₃/SrTiO₃ (LAO/STO) interface.

The LAO/STO interface has been widely studied and exhibits functional phenomena such as gate-tuneable superconductivity and ferromagnetism. When brought together, the ionic polar discontinuity generates a shift in electronic charge resulting in the formation of a high mobility 2D electron gas. Analogous to the way semiconductors are chemically doped, this provides intrinsic carrier doping without the structural disorder added by chemical dopants. This charge transfer effect is also predicted to arise between a metal and a band insulator, provided the band edges of the candidate materials are suitably aligned. Although widely studied, these interfacial properties are difficult to harness into application. LAO/STO heterostructures are made with precise techniques, requiring specific substrate termination and an exact number of unit cells to observe the effect. This kind of carefully controlled growth is time-consuming, and controlled substrate termination requires chemical etching, often with toxic chemicals such as hydrofluoric acid (HF). Moreover, the high mobility carriers are localised at the interface within a few unit cells and is difficult to access.

High-performance, transparent conducting materials (TCMs), for example transparent conducting oxides (TCOs), are in high demand due to their widespread application in display screen technologies and photovoltaics. Whereas heavily doped, wide band gap semiconductors have been the focus of research growth in the past, correlated metals have shown to be a promising alternative. Electronic correlation refers to electrostatic interactions between electrons causing a change in the effective carrier mass. To account for this, the band mass m_{band}* is renormalized by factor Zₖ giving the re-normalised carrier mass, mᵣ*=m_{band}*/Zₖ. This results in a reduced electrical conductivity, (2),

$$σ = \frac{{q}^{2} \cdot τ \cdot {n}_{eff}}{{m}^{*}}$$

where τ the scattering time of the carrier.

To identify a candidate transparent conducting material, electrical conductivity and optical transmission are assessed, but due to their antagonistic dependencies, optimal property tuning is challenging. Suitable transparent conducting materials (TCMs) are identified primarily via a high electrical conductivity and a small optical absorption in the visible part of the spectrum (1.75-3.2 eV).

Optical transmission is partially governed by free carrier reflection represented by the screened plasma frequency ωₚ given by:

$${ω}_{p} = \frac{q}{2 π \cdot \sqrt{{ε}_{0} {ε}_{r}}} \cdot \sqrt{\frac{{n}_{eff}}{{m}^{*}}}$$

where q is the electrical charge, ε₀ the permittivity of space, εᵣ the relative permittivity of the compound (also known as dielectric constant), n_{eff} the effective carrier concentration and m* the effective mass of the carrier. Due to the large intrinsic carrier density in conventional metals, the free carrier reflection is generally within or above the visible spectrum. In correlated metals, the plasma frequency is reduced to the near infrared via increased effective mass minimising the impact on visible light transmission despite the large metallic carrier density.

Interband transitions define light absorption in a material and therefore are also a key controllable parameter for optical transmission. The energy of interband transitions are determined intrinsically by the B-site transition metal frontier orbital energies and can be identified experimentally in the complex dielectric function.

Due to the large intrinsic carrier density in conventional metals, the free carrier reflection is generally within or above the visible spectrum. In correlated metals, the plasma frequency can be reduced to the near infrared via increased effective mass minimising the impact on visible light transmission despite a large metallic carrier density.

Transparent conducting oxides (TCOs) are the current front-running commercial materials with tin-doped indium oxide (ITO) and fluorine-doped tin oxide (FTO) being the most widely used. These compounds are wide bandgap (>3 eV) semiconductor oxides with no intraband transition in the visible spectrum, therefore offering high transparency. A high level of doping shifts the Fermi level into the conduction band to provide metallic-like electrical conduction, with the free carrier reflection edge (represented by the screened plasma frequency ωₚ below the near-infrared region of the spectrum (<1.75 eV). In these classical degenerately doped semiconductor TCOs, there is direct competition between screened plasma frequency ωₚ and the electrical conductivity σ, which are both controlled by the effective carrier concentration n_{eff} and the effective mass m* of the carrier, but in antagonistic ways. This competition governs the optimization of the effective carrier concentration n_{eff} and the effective mass m* of the carrier in wide bandgap TCOs, where increase in carrier density and a reduction of effective mass is pursued to maximize conductivity, at the cost of increasing the plasma frequency while simultaneously reducing transparency in the visible. The overall performance of the TCO is quantified by the Haacke figure of merit (FOM), Φ_{TC}=T¹⁰/Rₛ, where T is the average transmission in the visible and Rₛ is the sheet resistance. In practice, the maximum attainable conductivity in semiconductors is fundamentally limited, as increasing dopant concentration to raise the number of carriers decreases carrier mobility due to ionized impurity scattering and grain boundaries. Other practical limitations of doped semiconductor TCOs include low solubility limit of the dopant, toxicity of common dopants such as fluorine in FTO (with the use of hydrofluoric acid (HF) in the production process) and the scarcity of In increasing the cost of ITO. The current alternative to TCO materials is a very thin layer of a conventional metal such as Ag. In this case the overall performance of the material as a TCM is limited by the large electron mean free path of conventional metals (˜50 nm) increasing the interfacial scattering and therefore reducing the coating conductivity.

The intrinsic limit to enhance conventional semiconductors through chemical doping is well known. However, like traditional semiconductors, correlated metals also appear to reach an intrinsic limit to the tunability of their properties, with reports showing the Haacke figure of merit reaching a maximum of 3.4×10⁻³Ω⁻¹. Some enhancement can be gained from selection of the electronic configuration, B-site cation and band-width tuning, but the high carrier density and increased effective mass limit further tuning via these controls.

Hence, there is a need to improve transparent conducting materials.

### SUMMARY OF THE INVENTION

It is one aim of the present invention, amongst others, to provide a transparent conducting material which at least partially obviates or mitigates at least some of the disadvantages of the prior art, whether identified herein or elsewhere. For instance, it is an aim of embodiments of the invention to provide a transparent conducting material having an improved Haacke figure of merit.

A first aspect provides a film comprising a set of layers including a first layer, a third layer and a second layer therebetween;
wherein the first layer comprises and/or is a transparent conductive oxide having a formula:

A¹B¹O_{3-δ}_{₁};
wherein the third layer comprises and/or is a transparent wide-bandgap semiconductor oxide having a formula:

A³B³O_{3-δ}_{₃};
wherein the second layer comprises and/or is an oxide having a formula:

Aα¹A_{1-α}³B¹O_{3-δ}_{₂} or A_{α}¹A_{1-α}³B³O_{3-δ}_{₂} or A³Bβ¹B_{1-β}³O_{3-β}_{₂} or Aα¹A_{1-α}³B_{β}¹B_{1-β}³O_{3-β}_{₂};
wherein 0<α, β<1, −0.5≤δ₁, δ₂, δ₃≤0.5.

A second aspect provides an electrode comprising a film according to the first aspect on a substrate.

A third aspect provides a method of providing a film according to the first aspect, comprising: depositing the first layer on the third layer, for example by pulsed laser deposition.

### DETAILED DESCRIPTION OF THE INVENTION

According to the present invention there is provided a film, as set forth in the appended claims. Also provided is an electrode comprising such a film and a method of providing such a film. Other features of the invention will be apparent from the dependent claims, and the description that follows.

Film

The first aspect provides a film comprising a set of layers including a first layer, a third layer and a second layer therebetween;
wherein the first layer comprises and/or is a transparent conductive oxide having a formula:

A¹B¹O_{3-δ}_{₁};
wherein the third layer comprises and/or is a transparent wide-bandgap semiconductor oxide having a formula:

A³B³O_{3-δ}_{₃};
wherein the second layer comprises and/or is an oxide having a formula:

Aα¹A_{1-α}³B¹O_{3-δ}_{₂} or A_{α}¹A_{1-α}³B³O_{3-δ}_{₂} or A³Bβ¹B_{1-β}³O_{3-β}_{₂} or Aα¹A_{1-α}³B_{β}¹B_{1-β}³O_{3-β}_{₂};
wherein 0<α, β<1, −0.5≤δ₁, δ₂, δ₃≤0.5.

By combining the mass enhancement gained through electron correlation with the possibility of increasing the conductivity with light, high mobility carriers, a new design parameter to optimise these transparent conducting materials has been identified by the inventors. Particularly, the inventors have demonstrated that intrinsic charge transfer in the second layer (also known as an interface layer), for example SrNbO₃/SrTiO₃ (SNO/STO) interface, may be harnessed to enhance electronic conductivity in transparent correlated metal perovskite oxide interfaces and out-perform other correlated metal TCOs and traditional wide-gap semiconductors.

One of the advantages of the film is that by having a conductive first layer (for example, SNO), it is possible to easily extract/make use of the highly mobile electrons in the second (interface) layer while maintaining the high transparency. It might be possible to replicate the highly mobile second layer using as insulating oxide as the second layer e.g. Nb₂O₅ or NbO₂ but it would be very difficult to extract the electrons from the second layer.

In otherwords, the third layer comprises and/or is the transparent wide-bandgap semiconductor oxide that is capable of being doped to provide high mobility carriers, for example STO or BaSnO₃, the first layer comprises and/or is the TCO or correlated metal that includes a suitable dopant for the transparent wide-bandgap semiconductor oxide of the third layer, for example SNO for STO and LaNiO₃ for BaSnO₃, whereby the oxide of the second or interface layer, for example formed by diffusion of dopant from the first layer to the third layer, has active high carrier mobility, thus providing an active high mobility layer. The oxide of the second layer may be compositionally homogeneous or may include a compositional gradient, as described below.

The second layer is also sufficiently thin enough that its optical absorption is low (for example, having a thickness in a range from 0.5 to 50 nm) but may be difficult to form as a conventional thin layer, for example in isolation. The TCO of the first layer, being a conductor, extracts and uses the active high mobility carriers of the second layer.

For example, for SNO (the TCO of the first layer) on STO (the transparent wide-bandgap semiconductor of the third layer), Nb doping from the SNO into the STO forms the doped Sr(Nb,Ti)O₃ oxide of the second layer.

For example, for LaNiO₃ (the TCO of the first layer) on BaSnO₃ (the transparent wide-bandgap semiconductor of the third layer), La doping from the LaNiO₃ into the BaSnO₃ forms the doped (La,Ba)SnO₃ oxide of the second layer.

In contrast, SNO on BaSnO₃ is unlikely to work since Sr or Nb are not suitable dopants for Ba or Sn respectively in BaSnO₃.

In particular, generating charge transfer between two insulators may result in a high mobility 2D electron gas (2DEG). This effect is predicted to arise between a metal and an insulator if band alignment is correct: for example, at the SrNbO₃/SrTiO₃ interface.

More generally, the first aspect provides a transparent conducting material that may be provided as a film, amongst other forms.

Oxide interfaces have shown a wealth of emergent phenomena, presenting remarkable physics beyond conventional semiconductors. Electronic reconstruction at a carefully engineered interface and confined polarisation, spin, and orbital degrees of freedom can lead to properties not observed in the isolated bulk materials. Notable examples include the combination of LaMnO₃ and SrMnO₃, both antiferromagnetic insulators, exhibiting double-exchange ferromagnetism at their interface, and the quantum Hall effect in a high-mobility electron gas between ZnO/Zn₁₋ₓMgₓO. A further key example is the LaAlO₃/SrTiO₃ (LAO/STO) interface. The LAO/STO interface has been widely studied and exhibits interesting functional phenomena such as gate-tuneable superconductivity and ferromagnetism. When brought together, the ionic polar discontinuity generates a shift in electronic charge resulting in the formation of a high mobility 2D electron gas. Analogous to the way semiconductors are chemically doped, this provides intrinsic carrier doping without the structural disorder added by chemical dopants.

Correlated metals have been shown to be potential candidate TCMs. Combining the mass enhancement with the possibility of increasing the carrier concentration with high mobility carrier adds a new design parameter to optimise these materials but would require an abrupt interface and the large difference in carrier concentration between the 2DEG and the correlated metal would generate an electrostatic barrier to inject the highly mobile carrier in the metal.

In more detail, STO is a semiconductor with 3.2 eV band gap and can be doped n or p-type. Hydrogenic theory of shallow donors can be applied to STO with some caveats but qualitatively comparable to experimental results. STO exhibits unusual dielectric properties—the dielectric constant is strongly temperature dependant and high. For example, the dielectric constant εᵣ of STO is about 300 at 300K but tens of thousands at lower temperatures. The dielectric response is used to interpret unexpectedly high mobility at low temperatures of STO. For example, n type conduction may be achieved by substituting La³⁺ for Sr²⁺, Nb⁵⁺ for Ti⁴⁺ or by reduction of SrTiO_{3-δ}, where in a simple picture, each O vacancy generates two doped electrons. Thus, STO exhibits a high-mobility metallic state with strongly temperature-dependent resistivity, which persists down to the lowest carrier-densities probed, in the absence of carrier freeze out. Most highly reduced STO (reduced at a temperature of 1100° C.) had resistivity of 2.71 Ω·cm at 300K and residual resistance ratio (RRR) of 2710 and estimated carrier concentration of 10¹⁷ m⁻³. Nb doping may typically be from 0.02 at. % to 2.0 at. %.

The correlated metal SrNbO₃ exhibits excellent performance in the visible and the UV regime from 260 to 320 nm. This UV transparent conductor uses the energetically isolated conduction band originating from the Nb 4d orbitals and a sizeable electron correlation present in SrNbO₃ (c.f. vanadates in the visible spectrum). Many body effects arising from strong electron-electron interactions affect transport properties and optical response of the carriers in correlated metals and are quantified by the renormalization constant Zₖ. If the electron interaction strength is negligible Zₖ=1 and itinerant carriers respond like a free electron gas. Conversely, if Zₖ=0, as a consequence of a strong electron interaction, all free carriers are localized at lattice sites (Mott insulator). Alternatively, if the renormalization constant is 0<Zₖ<1, electrons maintain their itinerant character but their dynamic properties, such as the carrier mass m*, are renormalized, as described previously. For correlated metals, the renormalized carrier mass mᵣ* is increased relative to the band effective mass m_{band}* by the inverse of the renormalization constant Zₖ. Hence, the reduced plasma frequency ωₚ shifts towards the IR despite a metal-like carrier concentration n_{eff}. Although the increase in effective mass m_{band}* reduces partly the electrical conductivity σ, typical electrical conductivities of correlated metals have been found to be about one order of magnitude higher than that of ITO and more than three orders of magnitude higher than those of doped β-Ga₂O₃ and ZnGa₂O₄. However, while correlated oxides having perovskite structures have been demonstrated to behave as conventional transparent conductors, significant losses to optical transparency in the visible range arise to the location of their absorption edges. For example, for SrVO₃, the absorption edge is located at about 2.9 eV (427 nm), with the large absorption arising from an interband transition from oxygen 2p bands forming the valence band to the unoccupied states of the conduction band derived from the t2g orbitals of the transition metal element vanadium. However, this interband absorption edge may be shifted to higher energy if the electronegativity difference Δχ between the transition metal cation and oxygen anion is increased. Hence, by choosing a transition metal, for example, having a larger Δχ with respect to the oxygen anion (i.e. less electronegative compared with vanadium) but a similar electronic configuration, increases the energy difference between O 2p and transition metal t2g bands, causing the absorption edge to be located at higher photon energies. For example, niobium Nb⁴⁺ is isoelectronic with respect to V⁴⁺ but has a lower electronegativity (1.690 for Nb⁴⁺ compared with 1.795 for V⁴*). Hence, by replacing V⁴⁺ with Nb⁴⁺, Δχ is increased by about 6%, thereby shifting the interband absorption edge beyond the visible range and into the UV range (i.e. blue shift). Furthermore, by replacing at least some V⁴⁺ with Nb⁴⁺, the electron correlation strength is reduced. Particularly, the size of d-orbitals for Nb⁴⁺ is larger than compared with V⁴⁺, so that the orbital overlap and thus the bandwidth W of the conduction band is also larger for SrNbO₃ compared with SrVO₃, despite having a larger lattice parameter α (4.02 Å for SrNbO₃ compared with 3.84 Å for SrVO₃). By reducing the electron correlation strength, the renormalization constant Zₖ→1, thereby lowering mᵣ* and in turn, decreasing the correlation induced red-shift of the reduced plasma frequency that could otherwise reduce optical transparency of SrNbO₃ at long wavelengths of the visible spectrum.

This charge transfer effect is also expected to arise between a metal and a band insulator, provided the band edges of the candidate materials are suitably aligned. Theoretical work by Zhong and Hansmann (Zhicheng Zhong and Philipp Hansmann, Band Alignment and Charge Transfer in Complex Oxide Interfaces, PHYSICAL REVIEW X 7, 011023 (2017), DOI: 10.1103/PhysRevX.7.011023) predicts the effects of interfacing transition metal-oxides starting from basic laws defined for semiconductors. In a simple case of two ideal cubic perovskites, ABO₃ and AB′O₃ forming a heterostructure, a smooth structural transition and a shared oxygen matrix imply the boundary condition that oxygen states are continuous across the boundary. For materials with different local oxygen energy levels, this would result in a mismatch of Fermi energy E_{F}. Since E_{F} must be constant throughout a heterostructure in equilibrium, a transfer of charge occurs between the materials. The direction and strength of the charge transfer is determined by the difference in the bulk oxygen 2p energies with respect to their Fermi level. DFT studies of a variety of bulk compounds predicts the strength and size of the charge transfer in a single interface and in layered heterostructures. Although counterintuitive, charge transfer would not occur from the partially filled 3d¹ SrVO₃ to the empty d states of SrTiO₃ (STO), due to the higher energy of the oxygen states in the latter. However, the lower energy oxygen states in 4d¹ compounds SrNbO₃ (SNO) compared with STO, allow for a substantial electron transfer from the Nb 4d to the Ti 3d states. This allows for controlled electron doping via charge transfer of one of the most widely used transition metal oxides, inducing accessible high mobility electronic conduction.

Film

The film comprises the set of layers including the first layer, the third layer and the second layer therebetween. It should be understood that the second layer comprises and/or is an interface layer, disposed at the interface between the first layer and the third layer.

It should be understood that A¹, A³, B¹ and B³ are different from each other and deviations from ideal oxygen stoichiometry are given by δ₁, δ₂, δ₃. It should be understood that A¹, A³, B¹ and B³ may respectively represent one or more cations.

First Layer

The first layer comprises and/or is the transparent conductive oxide (TCO) (also known as a transparent correlated metal or a correlated metal) having the formula:

A¹B¹O_{3-δ}_{₁}.

TCOs are known. See, for example, Y. Tokura Correlated-Electron Physics in Transition-Metal Oxides, Physics Today, 2003, 56, 50 (https://doi.org/10.10631/1.1603080).

In one example the first layer has the formula:

$${A}_{1 - x}^{1 , 1} {A}_{x}^{1 , 2} {B}_{1 - y}^{1 , 1} {B}_{y}^{1 , 2} {O}_{3 - {δ}_{1}} or {( {A}^{1 , 1} {B}^{1 , 1} {O}_{3 - {δ}_{1 , 1}} )}_{j} {( {A}^{1 , 2} {B}^{1 , 2} {O}_{3 - {δ}_{1 , 2}} )}_{k} ;$$

wherein 0<x, y<1, −0.5≤δ₁, (δ_{1,1}+δ_{1,2})≤0.5 and j, k account for the thickness of individual nano-laminates in units of the perovskite unit cell, for example 1≤j, k≤10, for a TCO having such a laminated structure. It should be understood that A^{1,1}, A^{1,2}, B^{1,1} and B^{1,2} are different from each other and deviations from ideal oxygen stoichiometry are given by δ₁, δ_{1,1}, δ_{1,2}. Generally, this notation is applied similarly, mutatis mutandis.

Generally, A¹ represents one or more divalent alkaline earth cations, one or more trivalent cations and/or one or more monovalent cations. In one example, A¹ is selected from Group 2 (Be, Mg, Ca, Sr, Ba, Ra; preferably Ca, Sr, Ba) and/or the Lanthanides (La, Ce, Pr, Nd, Pm, Sm, Eu, Gd, Tb, Dy, Ho, Er, Tm, Yb, Lu; preferably La, Pr, Nd). In one example, A¹ is one or more divalent alkaline earth cations selected from Ca, Sr, Ba, preferably Sr. A^{1,1} and/or A^{1,2} may be as described with respect to A¹.

Generally, B¹ represents a transition metal selected from Group 5, Group 6, Group 10 and/or Group 4 and/or a metal selected from Group 14 and/or Group 13. In one example, B¹ is selected from Group 5 (V, Nb, Ta, db; preferably V, Nb, Ta), Group 6 (Cr, Mo, W, Sg; preferably Cr, Mo, W) and/or Group 10 (Ni, Pd, Pt, Ds; preferably Ni). In one example, B¹ is one or more transition metal cations selected from V, Nb, preferably Nb. B^{1,1} and/or B^{1,2} may be as described with respect to B¹.

In one example, A¹ and B¹ are according to Table 1.

TABLE 1
A¹ and B¹.

| A¹ | B¹ |
|---|---|
| Ca | V |
| Ca | Nb |
| Ca | Ta |
| Ca | Cr |
| Ca | Mo |
| Ca | W |
| Ca | Ni |
| Sr | V |
| Sr | Nb |
| Sr | Ta |
| Sr | Cr |
| Sr | Mo |
| Sr | W |
| Sr | Ni |
| Ba | V |
| Ba | Nb |
| Ba | Ta |
| Ba | Cr |
| Ba | Mo |
| Ba | W |
| Ba | Ni |
| La | V |
| La | Nb |
| La | Ta |
| La | Cr |
| La | Mo |
| La | W |
| La | Ni |
| Pr | V |
| Pr | Nb |
| Pr | Ta |
| Pr | Cr |
| Pr | Mo |
| Pr | W |
| Pr | Ni |
| Nd | V |
| Nd | Nb |
| Nd | Ta |
| Nd | Cr |
| Nd | Mo |
| Nd | W |
| Nd | Ni |

In one example, the first layer has an electron mobility in a range from 1 to 100 cm²V⁻¹s⁻¹, a carrier density in a range from 1×10²⁰ to 1×10²⁴ cm⁻³, a transmittance in a range from 75% to 100% at a wavelength of 550 nm, a thickness in a range from 2 to 100 nm, an effective mass in a range from 1 to 10 m₀ and/or a conductivity in a range from 1,000 to 100,000 Scm⁻¹ at room temperature.

Third Layer

The third layer comprises and/or is the transparent wide-bandgap semiconductor oxide having the formula:

A³B³O_{3-δ}_{₃}.

Transparent wide-bandgap semiconductor oxides are known. See, for example, Wide Bandgap Perovskite Oxides with High Room-Temperature Electron Mobility, Abhinav Prakash and Bharat Jalan, 6 Jul. 2019, Advanced Material Interfaces, 2019, 6, 1900479, https://doi.org/10.1002/admi.201900479.

In one example, A³ and/or is B³ is selected for adjusting a Fermi level position in a conduction band of the TCO of the first layer.

In one example, the transparent wide-bandgap semiconductor oxide has the formula:

$${A}_{1 - u}^{3 , 1} {A}_{u}^{3 , 2} {B}_{1 - ν}^{3 , 1} {B}_{ν}^{3 , 2} {O}_{3 - {δ}_{3}} or {( {A}^{3 , 1} {B}^{3 , 1} {O}_{3 - {δ}_{3 , 1}} )}_{m} {( {A}^{3 , 2} {B}^{3 , 1} {O}_{3 - {δ}_{3 , 2}} )}_{n} ;$$

wherein 0<u, v<1, −0.5≤δ₃, (δ_{3,1}+δ_{3,2})≤0.5 and m, n account for the thickness of individual nano-laminates in units of the perovskite unit cell, for example 1≤m, n≤10, for a transparent wide-bandgap semiconductor oxide having such a laminated structure. It should be understood that A^{3,1}, A^{3,2} B^{3,1} and B^{3,2} are different from each other and deviations from ideal oxygen stoichiometry are given by δ₃, δ_{3,1}, δ_{3,2}. Generally, this notation is applied similarly, mutatis mutandis.

In one example, A³ is selected from Group 2 (Be, Mg, Ca, Sr, Ba, Ra; preferably Ca, Sr, Ba), Group 12 (Zn, Cd, Hg, Cn; preferably Zn, Cd) and/or the Lanthanides (La, Ce, Pr, Nd, Pm, Sm, Eu, Gd, Tb, Dy, Ho, Er, Tm, Yb, Lu; preferably La, Pr, Nd). In one example, A³ is one or more divalent alkaline earth cations selected from Ca, Sr, Ba, preferably Sr or Ba. A^{3,1} and/or A^{3,2} may be as described with respect to A³.

In one example, B³ is selected from Group 4 (Ti, Zr, Hf, Rf; preferably Ti) and/or Group 14 (C, Si, Ge, Sn, Pb, UUq; preferably Sn). In one example, B³ is one or more transition metal cations selected from Ti, Zr, preferably Ti; and/or wherein B⁴ is one or more metal cations selected from Sn. B^{3,1} and/or B^{3,2} may be as described with respect to B³.

In one example, A³ and B³ are according to Table 2.

A³ and B³.

| A³ | B³ |
|---|---|
| Ca | Ti |
| Ca | Sn |
| Sr | Ti |
| Sr | Sn |
| Ba | Ti |
| Ba | Sn |
| Zn | Ti |
| Zn | Sn |
| Cd | Ti |
| Cd | Sn |
| La | Ti |
| La | Sn |
| Pr | Ti |
| Pr | Sn |
| Nd | Ti |
| Nd | Sn |

In one example, A³ is one or more alkali metal cations selected from group 1 and/or one or more trivalent lanthanide cations and/or A³ is one or more alkali metal cations selected from group 1 and/or one or more trivalent lanthanide cations), for adjusting a Fermi level position in a conduction band of the TCO of the first layer.

In one example, B³ is one or more transition metal cations selected from Groups 4, 6 and/or one or more metal cations selected from Groups 13, 14 and/or B³ is one or more transition metal cations selected from Groups 4, 6 and/or one or more metal cations selected from groups 13, 14, for adjusting a Fermi level position in a conduction band of the TCO of the first layer.

Second Layer

The second layer comprises and/or is the oxide layer having the formula:

Aα¹A_{1-α}³B¹O_{3-δ}_{₂} or A_{α}¹A_{1-α}³B³O_{3-δ}_{₂} or A³Bβ¹B_{1-β}³O_{3-β}_{₂} or Aα¹A_{1-α}³B_{β}¹B_{1-β}³O_{3-β}_{₂};
wherein 0<α, β<1, −0.5≤δ₁, δ₂, δ₃≤0.5.

If the formula is A_{α}¹A_{1-α}³B¹O_{3-δ}_{₂}, A¹ site substitution of the TCO of the first layer by A³ is present. Examples of such A¹ site substitution include where the transparent wide-bandgap semiconductor oxide is SrTiO₃ or a stannate such as BaSnO₃, CaSnO₃, SrSnO₃, ZnSnO₃ or CdSnO₃ (i.e. A³: Group 2 or Group 12; B³: Group 14) and the TCO is lanthanide vanadate, chromate or nickelate such as LaVO₃, LaCrO₃ or LaNiO₃ (i.e. A¹: lanthanide; B¹: Group 5, Group 6 or Group 10).

If the formula is A_{α}¹A_{1-α}³B³O_{3-δ}_{₂}, A³ site substitution of the transparent wide-bandgap semiconductor oxide of the third layer by A¹ is present. Examples of such A³ site substitution include where the transparent wide-bandgap semiconductor oxide is BaSnO₃ (i.e. A³: Group 2; B³: Group 14) and the TCO is LaNiO₃ (i.e. A¹: lanthanide; B¹: Group 10).

If the formula is A³B_{β}¹B_{1-β}³O_{3-δ}_{₂}, B³ site substitution of the transparent wide-bandgap semiconductor oxide of the third layer by B¹ is present. Examples of such B³ site substitution include where the transparent wide-bandgap semiconductor oxide is SrTiO₃, BaSnO₃ or LaSnO₃ (i.e. A³: Group 2 or lanthanide; B³: Group 4 or Group 14) and the TCO is SrNbO₃, CaNbO₃, SrMoO₃, CaMoO₃ or SrVO₃ (i.e. A¹: Group 2; B¹: Group 5 or Group 6).

If the formula is A_{α}¹A_{1-α}³B_{β}¹B_{1-β}³O_{3-δ}_{₂}, A³ site substitution of the transparent wide-bandgap semiconductor oxide of the third layer by A¹ is present and B³ site substitution of the transparent wide-bandgap semiconductor oxide of the third layer by B¹ is present.

In one example, the second layer has an electron mobility in a range from 1 to 100 cm²V⁻¹s⁻¹ a carrier density in a range from 1×10²⁰ to 1×10²⁴ cm⁻³, a transmittance in a range from 75% to 100% at a wavelength of 550 nm, a thickness in a ranged from 0.5 to 5 nm, an effective mass in a range from 1 to 10 m₀ and/or a conductivity in a range from 1,000 to 100,000 Scm⁻¹ at room temperature.

### EXAMPLES

TABLE 3
Example films according to the first aspect.

| | | Third layer |
|---|---|---|
| First layer | | transparent |
| transparent conductive oxide | | wide-bandgap |
| aka correlated metal | Second layer | semiconductor |
| A¹ B¹ O_{3-δ}^{₁} | A_{α}¹A_{1-α}³B¹ O_{3-δ}^{₂} or | A³ B³ O_{3-δ}^{₃} |
| | A_{α}¹A_{1-α}³B³ O_{3-δ}^{₂} or | |
| | A³ B_{β}¹B_{1-β}³O_{3-δ}^{₂} or | |
| | A_{α}¹A_{1-α}³B_{β}¹B_{1-β}³O_{3-δ}^{₂} | |
| SrNbO₃ (SNO) | Sr(Nb, Ti)O₃ | SrTiO₃ (STO) |
| A¹ = Sr; B¹ = Nb | A³ B_{β}¹B_{1-β}³O_{3-δ}^{₂} | A³ = Sr; B³ = Ti |
| | A³ = Sr; B¹ = Nb; | |
| | B³ = Ti; 0 < β < 1 | |
| CaNbO₃ | Sr(Nb, Ti)O₃ | SrTiO₃ |
| A¹ = Ca; B¹ = Nb | A³ B_{β}¹B_{1-β}³O_{3-δ}^{₂} | A³ = Sr; B³ = Ti |
| | A³ = Sr; B¹ = Nb; | |
| | B³ = Ti; 0 < β < 1 | |
| SrVO₃ | Sr(V, Ti)O₃ | SrTiO₃ |
| A¹ = Sr; B¹ = V | A³ B_{β}¹B_{1-β}³O_{3-δ}^{₂} | A³ = Sr; B³ = Ti |
| | A³ = Sr; B¹ = V; | |
| | B³ = Ti; 0 < β < 1 | |
| CaVO₃ | Sr(V, Ti)O₃ | SrTiO₃ |
| A¹ = Ca; B¹ = V | A³ B_{β}¹B_{1-β}³O_{3-δ}^{₂} | A³ = Sr; B³ = Ti |
| | A³ = Sr; B¹ = V; | |
| | B³ = Ti; 0 < β < 1 | |
| SrMoO₃ | Sr(Mo, Ti)O₃ | SrTiO₃ |
| A¹ = Sr; B¹ = Mo | A³ B_{β}¹B_{1-β}³O_{3-δ}^{₂} | A³ = Sr; B³ = Ti |
| | A³ = Sr; B¹ = Mo; | |
| | B³ = Ti; 0 < β < 1 | |
| CaMoO₃ | Sr(Mo, Ti)O₃ | SrTiO₃ |
| A¹ = Ca; B¹ = Mo | A³ B_{β}¹B_{1-β}³O_{3-δ}^{₂} | A³ = Sr; B³ = Ti |
| | A³ = Sr; B¹ = Mo; | |
| | B³ = Ti; 0 < β < 1 | |
| LaVO₃ | Sr(V, Ti)O₃ | SrTiO₃ |
| A¹ = La; B¹ = V | A³ B_{β}¹B_{1-β}³O_{3-δ}^{₂} | A³ = Sr; B³ = Ti |
| | A³ = Sr; B¹ = V; | |
| | B³ = Ti; 0 < β < 1 | |
| LaCrO₃ | Sr(Cr, Ti)O₃ | SrTiO₃ |
| A¹ = La; B¹ = Cr | A³ B_{β}¹B_{1-β}³O_{3-δ}^{₂} | A³ = Sr; B³ = Ti |
| | A³ = Sr; B¹ = Cr; | |
| | B³ = Ti; 0 < β < 1 | |
| LaNiO₃ | (La, Ba)SnO₃ | BaSnO₃ |
| A¹ = La; B¹ = Ni | A_{α}¹A_{1-α}³B³ O_{3-δ}^{₂} | A³ = Ba; B³ = Sn |
| | A¹ = La; A³ = Ba; | |
| | B³ = Sn; 0 < α < 1 | |
| LaNiO₃ | (La, Ca)SnO₃ | CaSnO₃ |
| A¹ = La; B¹ = Ni | A_{α}¹A_{1-α}³B³ O_{3-δ}^{₂} | A³ = Ca; B³ = Sn |
| | A¹ = La; A³ = Ca; | |
| | B³ = Sn; 0 < α < 1 | |
| LaNiO₃ | (La, Sr)SnO₃ | SrSnO₃ |
| A¹ = La; B¹ = Ni | A_{α}¹A_{1-α}³B³ O_{3-δ}^{₂} | A³ = Sr; B³ = Sn |
| | A¹ = La; A³ = Sr; | |
| | B³ = Sn; 0 < α < 1 | |
| LaNiO₃ | (La, Zn)SnO₃ | ZnSnO₃ |
| A¹ = La; B¹ = Ni | A_{α}¹A_{1-α}³B³ O_{3-δ}^{₂} | A³ = Zn; B³ = Sn |
| | A¹ = La; A³ = Zn; | |
| | B³ = Sn; 0 < α < 1 | |
| LaNiO₃ | (La, Cd)SnO₃ | CdSnO₃ |
| A¹ = La; B¹ = Ni | A_{α}¹A_{1-α}³B³ O_{3-δ}^{₂} | A³ = Cd; B³ = Sn |
| | A¹ = La; A³ = Cd; | |
| | B³ = Sn; 0 < α < 1 | |
| A(V or Nb or Ta or Cr | Transition metal | BaTiO₃ |
| or Mo or W)O₃ where A | doped BaTiO₃ | |
| is an alkaline earth element, | | |
| preferably Ca, Sr, Ba | | |
| A(V or Nb or Ta or Cr | Transition metal | SrTiO₃ |
| or Mo or W)O₃ where A | doped SrTiO₃ | |
| is an alkaline earth element, | | |
| preferably Ca, Sr, Ba | | |
| A(V or Nb or Ta or Cr | Transition metal | CaTiO₃ |
| or Mo or W)O₃ where A | doped CaTiO₃ | |
| is an alkaline earth element, | | |
| preferably Ca, Sr, Ba | | |
| A(V or Nb or Ta or Cr | Transition metal | ZnTiO₃ |
| or Mo or W)O₃ where A | doped ZnTiO₃ | |
| is an alkaline earth element, | | |
| preferably Ca, Sr, Ba | | |

Table 4 includes examples of films according to the first aspect. A¹ and B¹ of the first layer and A³ and B³ of the third layer are shown and the compositions of the third layer shown at the intersections, thereby indicating the doping species. 1-x and x are analogous to 1−α and α, respectively. Oxygen content is nominal i.e. generally O_{3-β}_{₂}.

TABLE 4
Example films according to the first aspect.

| | | A³ | | | | | | | |
|---|---|---|---|---|---|---|---|---|---|
| | | Ca | Ca | Sr | Sr | Ba | Ba | Zn | Zn |
| | | B³ | | | | | | | |
| A¹ | B¹ | Ti | Sn | Ti | Sn | Ti | Sn | Ti | Sn |
| Ca | V | CaTi1-xVxO3 | | SrTi1-xVxO3 | | BaTi1-xVxO3 | | ZnTi1-xVxO3 | |
| Ca | Nb | CaTi1-xNbxO3 | | SrTi1-xNbxO3 | | BaTi1-xNbxO3 | | ZnTi1-xNbxO3 | |
| Ca | Ta | CaTi1-xTaxO3 | | SrTi1-xTaxO3 | | BaTi1-xTaxO3 | | ZnTi1-xTaxO3 | |
| Ca | Cr | CaTi1-xCrxO3 | | SrTi1-xCrxO3 | | BaTi1-xCrxO3 | | ZnTi1-xCrxO3 | |
| Ca | Mo | CaTi1-xMoxO3 | | SrTi1-xMoxO3 | | BaTi1-xMoxO3 | | ZnTi1-xMoxO3 | |
| Ca | W | CaTi1-xWxO3 | | SrTi1-xWxO3 | | BaTi1-xWxO3 | | ZnTi1-xWxO3 | |
| Ca | Ni | CaTi1-xNixO3 | | SrTi1-xNixO3 | | BaTi1-xNixO3 | | ZnTi1-xNixO3 | |
| Sr | V | CaTi1-xVxO3 | | SrTi1-xVxO3 | | BaTi1-xVxO3 | | ZnTi1-xVxO3 | |
| Sr | Nb | CaTi1-xNbxO3 | | SrTi1-xNbxO3 | | BaTi1-xNbxO3 | | ZnTi1-xNbxO3 | |
| Sr | Ta | CaTi1-xTaxO3 | | SrTi1-xTaxO3 | | BaTi1-xTaxO3 | | ZnTi1-xTaxO3 | |
| Sr | Cr | CaTi1-xCrxO3 | | SrTi1-xCrxO3 | | BaTi1-xCrxO3 | | ZnTi1-xCrxO3 | |
| Sr | Mo | CaTi1-xMoxO3 | | SrTi1-xMoxO3 | | BaTi1-xMoxO3 | | ZnTi1-xMoxO3 | |
| Sr | W | CaTi1-xWxO3 | | SrTi1-xWxO3 | | BaTi1-xWxO3 | | ZnTi1-xWxO3 | |
| Sr | Ni | CaTi1-xNixO3 | | SrTi1-xNixO3 | | BaTi1-xNixO3 | | ZnTi1-xNixO3 | |
| Ba | V | CaTi1-xVxO3 | | SrTi1-xVxO3 | | BaTi1-xVxO3 | | ZnTi1-xVxO3 | |
| Ba | Nb | CaTi1-xNbxO3 | | SrTi1-xNbxO3 | | BaTi1-xNbxO3 | | ZnTi1-xNbxO3 | |
| Ba | Ta | CaTi1-xTaxO3 | | SrTi1-xTaxO3 | | BaTi1-xTaxO3 | | ZnTi1-xTaxO3 | |
| Ba | Cr | CaTi1-xCrxO3 | | SrTi1-xCrxO3 | | BaTi1-xCrxO3 | | ZnTi1-xCrxO3 | |
| Ba | Mo | CaTi1-xMoxO3 | | SrTi1-xMoxO3 | | BaTi1-xMoxO3 | | ZnTi1-xMoxO3 | |
| Ba | W | CaTi1-xWxO3 | | SrTi1-xWxO3 | | BaTi1-xWxO3 | | ZnTi1-xWxO3 | |
| Ba | Ni | CaTi1-xNixO3 | | SrTi1-xNixO3 | | BaTi1-xNixO3 | | ZnTi1-xNixO3 | |
| La | V | CaTi1-xVxO3 | Ca1-xLaxSnO3 | SrTi1-xVxO3 | Sr1-xLaxSnO3 | BaTi1-xVxO3 | Ba1-xLaxSnO3: | ZnTi1-xVxO3 | Zn1-xLaxSnO3 |
| La | Nb | CaTi1-xNbxO3 | Ca1-xLaxSnO3 | SrTi1-xNbxO3 | Sr1-xLaxSnO3 | BaTi1-xNbxO3 | Ba1-xLaxSnO3: | ZnTi1-xNbxO3 | Zn1-xLaxSnO3 |
| La | Ta | CaTi1-xTaxO3 | Ca1-xLaxSnO3 | SrTi1-xTaxO3 | Sr1-xLaxSnO3 | BaTi1-xTaxO3 | Ba1-xLaxSnO3 | ZnTi1-xTaxO3 | Zn1-xLaxSnO3 |
| La | Cr | CaTi1-xCrxO3 | Ca1-xLaxSnO3 | SrTi1-xCrxO3 | Sr1-xLaxSnO3 | BaTi1-xCrxO3 | Ba1-xLaxSnO3 | ZnTi1-xCrxO3 | Zn1-xLaxSnO3 |
| La | Mo | CaTi1-xMoxO3 | Ca1-xLaxSnO3 | SrTi1-xMoxO3 | Sr1-xLaxSnO3 | BaTi1-xMoxO3 | Ba1-xLaxSnO3 | ZnTi1-xMoxO3 | Zn1-xLaxSnO3 |
| La | W | CaTi1-xWxO3 | Ca1-xLaxSnO3 | SrTi1-xWxO3 | Sr1-xLaxSnO3 | BaTi1-xWxO3 | Ba1-xLaxSnO3 | ZnTi1-xWxO3 | Zn1-xLaxSnO3 |
| La | Ni | CaTi1-xNixO3 | Ca1-xLaxSnO3 | SrTi1-xNixO3 | Sr1-xLaxSnO3 | BaTi1-xNixO3 | Ba1-xLaxSnO3 | ZnTi1-xNixO3 | Zn1-xLaxSnO3 |
| Pr | V | CaTi1-xVxO3 | Ca1-xPrxSnO3 | SrTi1-xVxO3 | Sr1-xPrxSnO3 | BaTi1-xVxO3 | Ba1-xPrxSnO3 | ZnTi1-xVxO3 | Zn1-xPrxSnO3 |
| Pr | Nb | CaTi1-xNbxO3 | Ca1-xPrxSnO3 | SrTi1-xNbxO3 | Sr1-xPrxSnO3 | BaTi1-xNbxO3 | Ba1-xPrxSnO3 | ZnTi1-xNbxO3 | Zn1-xPrxSnO3 |
| Pr | Ta | CaTi1-xTaxO3 | Ca1-xPrxSnO3 | SrTi1-xTaxO3 | Sr1-xPrxSnO3 | BaTi1-xTaxO3 | Ba1-xPrxSnO3 | ZnTi1-xTaxO3 | Zn1-xPrxSnO3 |
| Pr | Cr | CaTi1-xCrxO3 | Ca1-xPrxSnO3 | SrTi1-xCrxO3 | Sr1-xPrxSnO3 | BaTi1-xCrxO3 | Ba1-xPrxSnO3 | ZnTi1-xCrxO3 | Zn1-xPrxSnO3 |
| Pr | Mo | CaTi1-xMoxO3 | Ca1-xPrxSnO3 | SrTi1-xMoxO3 | Sr1-xPrxSnO3 | BaTi1-xMoxO3 | Ba1-xPrxSnO3 | ZnTi1-xMoxO3 | Zn1-xPrxSnO3 |
| Pr | W | CaTi1-xWxO3 | Ca1-xPrxSnO3 | SrTi1-xWxO3 | Sr1-xPrxSnO3 | BaTi1-xWxO3 | Ba1-xPrxSnO3 | ZnTi1-xWxO3 | Zn1-xPrxSnO3 |
| Pr | Ni | CaTi1-xNixO3 | Ca1-xNdxSnO3 | SrTi1-xNixO3 | Sr1-xNdxSnO3 | BaTi1-xNixO3 | Ba1-xNdxSnO3 | ZnTi1-xNixO3 | Zn1-xNdxSnO3 |
| Nd | V | CaTi1-xVxO3 | Ca1-xNdxSnO3 | SrTi1-xVxO3 | Sr1-xNdxSnO3 | BaTi1-xVxO3 | Ba1-xNdxSnO3 | ZnTi1-xVxO3 | Zn1-xNdxSnO3 |
| Nd | Nb | CaTi1-xNbxO3 | Ca1-xNdxSnO3 | SrTi1-xNbxO3 | Sr1-xNdxSnO3 | BaTi1-xNbxO3 | Ba1-xNdxSnO3 | ZnTi1-xNbxO3 | Zn1-xNdxSnO3 |
| Nd | Ta | CaTi1-xTaxO3 | Ca1-xNdxSnO3 | SrTi1-xTaxO3 | Sr1-xNdxSnO3 | BaTi1-xTaxO3 | Ba1-xNdxSnO3 | ZnTi1-xTaxO3 | Zn1-xNdxSnO3 |
| Nd | Cr | CaTi1-xCrxO3 | Ca1-xNdxSnO3 | SrTi1-xCrxO3 | Sr1-xNdxSnO3 | BaTi1-xCrxO3 | Ba1-xNdxSnO3 | ZnTi1-xCrxO3 | Zn1-xNdxSnO3 |
| Nd | Mo | CaTi1-xMoxO | Ca1-xNdxSnO3 | SrTi1-xMoxO3 | Sr1-xNdxSnO3 | BaTi1-xMoxO3 | Ba1-xNdxSnO3 | ZnTi1-xMoxO3 | Zn1-xNdxSnO3 |
| Nd | W | CaTi1-xWxO3 | Ca1-xNdxSnO3 | SrTi1-xWxO3 | Sr1-xNdxSnO3 | BaTi1-xWxO3 | Ba1-xNdxSnO3 | ZnTi1-xWxO3 | Zn1-xNdxSnO3 |
| Nd | Ni | CaTi1-xNixO3 | Ca1-xNdxSnO3 | SrTi1-xNixO3 | Sr1-xNdxSnO3 | BaTi1-xNixO3 | Ba1-xNdxSnO3 | ZnTi1-xNixO3 | Zn1-xNdxSnO3 |
| | | A³ | | | | | | | |
| | | Cd | Cd | La | La | Pr | Pr | Nd | Nd |
| | | B³ | | | | | | | |
| A¹ | B¹ | Ti | Sn | Ti | Sn | Ti | Sn | T | Sn |
| Ca | V | CdTi1-xVxO3 | | LaTi1-xVxO3 | Ca1-xLaxSnO3 | PrTi1-xVxO3 | Ca1-xPrxSnO3 | NdTi1-xVxO3 | Ca1-xNdxSnO3 |
| Ca | Nb | CdTi1-xNbxO3 | | LaTi1-xNbxO3 | Ca1-xLaxSnO3 | PrTi1-xNbxO3 | Ca1-xPrxSnO3 | NdTi1-xNbxO3 | Ca1-xNdxSnO3 |
| Ca | Ta | CdTi1-xTaxO3 | | LaTi1-xTaxO3 | Ca1-xLaxSnO3 | PrTi1-xTaxO3 | Ca1-xPrxSnO3 | NdTi1-xTaxO3 | Ca1-xNdxSnO3 |
| Ca | Cr | CdTi1-xCrxO3 | | LaTi1-xCrxO3 | Ca1-xLaxSnO3 | PrTi1-xCrxO3 | Ca1-xPrxSnO3 | NdTi1-xCrxO3 | Ca1-xNdxSnO3 |
| Ca | Mo | CdTi1-xMoxO3 | | LaTi1-xMoxO3 | Ca1-xLaxSnO3 | PrTi1-xMoxO3 | Ca1-xPrxSnO3 | NdTi1-xMoxO3 | Ca1-xNdxSnO3 |
| Ca | W | CdTi1-xWxO3 | | LaTi1-xWxO3 | Ca1-xLaxSnO3 | PrTi1-xWxO3 | Ca1-xPrxSnO3 | NdTi1-xWxO3 | Ca1-xNdxSnO3 |
| Ca | Ni | CdTi1-xNixO3 | | LaTi1-xNixO3 | Ca1-xLaxSnO3 | PrTi1-xNixO3 | Ca1-xPrxSnO3 | NdTi1-xNixO3 | Ca1-xNdxSnO3 |
| Sr | V | CdTi1-xVxO3 | | LaTi1-xVxO3 | Sr1-xPrxSnO3 | PrTi1-xVxO3 | Sr1-xPrxSnO3 | NdTi1-xVxO3 | Sr1-xNdxSnO3 |
| Sr | Nb | CdTi1-xNbxO3 | | LaTi1-xNbxO3 | Sr1-xPrxSnO3 | PrTi1-xNbxO3 | Sr1-xPrxSnO3 | NdTi1-xNbxO3 | Sr1-xNdxSnO3 |
| Sr | Ta | CdTi1-xTaxO3 | | LaTi1-xTaxO3 | Sr1-xPrxSnO3 | PrTi1-xTaxO3 | Sr1-xPrxSnO3 | NdTi1-xTaxO3 | Sr1-xNdxSnO3 |
| Sr | Cr | CdTi1-xCrxO3 | | LaTi1-xCrxO3 | Sr1-xPrxSnO3 | PrTi1-xCrxO3 | Sr1-xPrxSnO3 | NdTi1-xCrxO3 | Sr1-xNdxSnO3 |
| Sr | Mo | CdTi1-xMoxO3 | | LaTi1-xMoxO3 | Sr1-xPrxSnO3 | PrTi1-xMoxO3 | Sr1-xPrxSnO3 | NdTi1-xMoxO3 | Sr1-xNdxSnO3 |
| Sr | W | CdTi1-xWxO3 | | LaTi1-xWxO3 | Sr1-xPrxSnO3 | PrTi1-xWxO3 | Sr1-xPrxSnO3 | NdTi1-xWxO3 | Sr1-xNdxSnO3 |
| Sr | Ni | CdTi1-xNixO3 | | LaTi1-xNixO3 | Sr1-xNdxSnO3 | PrTi1-xNixO3 | Sr1-xPrxSnO3 | NdTi1-xNixO3 | Sr1-xNdxSnO3 |
| Ba | V | CdTi1-xVxO3 | | LaTi1-xVxO3 | Ba1-xNdxSnO3 | PrTi1-xVxO3 | Ba1-xPrxSnO3 | NdTi1-xVxO3 | Ba1-xNdxSnO3 |
| Ba | Nb | CdTi1-xNbxO3 | | LaTi1-xNbxO3 | Ba1-xNdxSnO3 | PrTi1-xNbxO3 | Ba1-xPrxSnO3 | NdTi1-xNbxO3 | Ba1-xNdxSnO3 |
| Ba | Ta | CdTi1-xTaxO3 | | LaTi1-xTaxO3 | Ba1-xNdxSnO3 | PrTi1-xTaxO3 | Ba1-xPrxSnO3: | NdTi1-xTaxO3 | Ba1-xNdxSnO3 |
| Ba | Cr | CdTi1-xCrxO3 | | LaTi1-xCrxO3 | Ba1-xNdxSnO3 | PrTi1-xCrxO3 | Ba1-xPrxSnO3 | NdTi1-xCrxO3 | Ba1-xNdxSnO3 |
| Ba | Mo | CdTi1-xMoxO3 | | LaTi1-xMoxO3 | Ba1-xNdxSnO3 | PrTi1-xMoxO3 | Ba1-xPrxSnO3 | NdTi1-xMoxO3 | Ba1-xNdxSnO3 |
| Ba | W | CdTi1-xWxO3 | | LaTi1-xWxO3 | Ba1-xNdxSnO3 | PrTi1-xWxO3 | Ba1-xPrxSnO3 | NdTi1-xWxO3 | Ba1-xNdxSnO3 |
| Ba | Ni | CdTi1-xNixO3 | | LaTi1-xNixO3 | Ba1-xNdxSnO3 | PrTi1-xNixO3 | Ba1-xPrxSnO3 | NdTi1-xNixO3 | Ba1-xNdxSnO3 |
| La | V | CdTi1-xVxO3 | Cd1-xLaxSnO3 | LaTi1-xVxO3 | | PrTi1-xVxO3 | | NdTi1-xVxO3 | |
| La | Nb | CdTi1-xNbxO3 | Cd1-xLaxSnO3 | LaTi1-xNbxO3 | | PrTi1-xNbxO3 | | NdTi1-xNbxO3 | |
| La | Ta | CdTi1-xTaxO3 | Cd1-xLaxSnO3 | LaTi1-xTaxO3 | | PrTi1-xTaxO3 | | NdTi1-xTaxO3 | |
| La | Cr | CdTi1-xCrxO3 | Cd1-xLaxSnO3 | LaTi1-xCrxO3 | | PrTi1-xCrxO3 | | NdTi1-xCrxO3 | |
| La | Mo | CdTi1-xMoxO3 | Cd1-xLaxSnO3 | LaTi1-xMoxO3 | | PrTi1-xMoxO3 | | NdTi1-xMoxO3 | |
| La | W | CdTi1-xWxO3 | Cd1-xLaxSnO3 | LaTi1-xWxO3 | | PrTi1-xWxO3 | | NdTi1-xWxO3 | |
| La | Ni | CdTi1-xNixO3 | Cd1-xLaxSnO3 | LaTi1-xNixO3 | | PrTi1-xNixO3 | | NdTi1-xNixO3 | |
| Pr | V | CdTi1-xVxO3 | Cd1-xPrxSnO3 | LaTi1-xVxO3 | | PrTi1-xVxO3 | | NdTi1-xVxO3 | |
| Pr | Nb | CdTi1-xNbxO3 | Cd1-xPrxSnO3 | LaTi1-xNbxO3 | | PrTi1-xNbxO3 | | NdTi1-xNbxO3 | |
| Pr | Ta | CdTi1-xTaxO3 | Cd1-xPrxSnO3 | LaTi1-xTaxO3 | | PrTi1-xTaxO3 | | NdTi1-xTaxO3 | |
| Pr | Cr | CdTi1-xCrxO3 | Cd1-xPrxSnO3 | LaTi1-xCrxO3 | | PrTi1-xCrxO3 | | NdTi1-xCrxO3 | |
| Pr | Mo | CdTi1-xMoxO3 | Cd1-xPrxSnO3 | LaTi1-xMoxO3 | | PrTi1-xMoxO3 | | NdTi1-xMoxO3 | |
| Pr | W | CdTi1-xWxO3 | Cd1-xPrxSnO3 | LaTi1-xWxO3 | | PrTi1-xWxO3 | | NdTi1-xWxO3 | |
| Pr | Ni | CdTi1-xNixO3 | Cd1-xNdxSnO3 | LaTi1-xNixO3 | | PrTi1-xNixO3 | | NdTi1-xNixO3 | |
| Nd | V | CdTi1-xVxO3 | Cd1-xNdxSnO3 | LaTi1-xVxO3 | | PrTi1-xVxO3 | | NdTi1-xVxO3 | |
| Nd | Nb | CdTi1-xNbxO3 | Cd1-xNdxSnO3 | LaTi1-xNbxO3 | | PrTi1-xNbxO3 | | NdTi1-xNbxO3 | |
| Nd | Ta | CdTi1-xTaxO3 | Cd1-xNdxSnO3 | LaTi1-xTaxO3 | | PrTi1-xTaxO3 | | NdTi1-xTaxO3 | |
| Nd | Cr | CdTi1-xCrxO3 | Cd1-xNdxSnO3 | LaTi1-xCrxO3 | | PrTi1-xCrxO3 | | NdTi1-xCrxO3 | |
| Nd | Mo | CdTi1-xMoxO3 | Cd1-xNdxSnO3 | LaTi1-xMoxO3 | | PrTi1-xMoxO3 | | NdTi1-xMoxO3 | |
| Nd | W | CdTi1-xWxO3 | Cd1-xNdxSnO3 | LaTi1-xWxO3 | | PrTi1-xWxO3 | | NdTi1-xWxO3 | |
| Nd | Ni | CdTi1-xNixO3 | Cd1-xNdxSnO3 | LaTi1-xNixO3 | | PrTi1-xNixO3 | | NdTi1-xNixO3 | |

In one example, the second layer comprises and/or is a compositionally-graded layer, optionally having a linear composition gradient therethrough. In this way, the carrier concentration is increased (and hence the overall conductivity) while the transparency is governed by the bulk of the heterostructure (correlated metal).

In one example, the second layer has a thickness in a range from 0.5 Å to 100 Å, preferably in a range from 2 Å to 80 Å, more preferably in a range from 5 Å to 50 Å, most preferably in a range from 10 Å to 25 Å.

Electrode

The second aspect provides an electrode comprising a film according to the first aspect on a substrate.

In one example, the electrode is included in a display screen, photovoltaics, energy saving glazing, a touch screens and/or a LED.

An aspect provides a device, for example a display screen, photovoltaics, energy saving glazing, a touch screens and/or a LED, comprising an electrode according to the second aspect.

Method

The third aspect provides a method of providing a film according to the first aspect, comprising: depositing the first layer on the third layer, for example by pulsed laser deposition.

In one example, the method comprises diffusing at least some of B¹ (i.e. from the TCO) into the third layer (i.e. into the transparent wide-bandgap semiconductor), thereby providing the second layer.

### Definitions

Throughout this specification, the term “comprising” or “comprises” means including the component(s) specified but not to the exclusion of the presence of other components. The term “consisting essentially of” or “consists essentially of” means including the components specified but excluding other components except for materials present as impurities, unavoidable materials present as a result of processes used to provide the components, and components added for a purpose other than achieving the technical effect of the invention, such as colourants, and the like.

The term “consisting of” or “consists of” means including the components specified but excluding other components.

Whenever appropriate, depending upon the context, the use of the term “comprises” or “comprising” may also be taken to include the meaning “consists essentially of” or “consisting essentially of”, and also may also be taken to include the meaning “consists of” or “consisting of”.

The optional features set out herein may be used either individually or in combination with each other where appropriate and particularly in the combinations as set out in the accompanying claims. The optional features for each aspect or exemplary embodiment of the invention, as set out herein are also applicable to all other aspects or exemplary embodiments of the invention, where appropriate. In other words, the skilled person reading this specification should consider the optional features for each aspect or exemplary embodiment of the invention as interchangeable and combinable between different aspects and exemplary embodiments.

### BRIEF DESCRIPTION OF THE DRAWINGS

For a better understanding of the invention, and to show how exemplary embodiments of the same may be brought into effect, reference will be made, by way of example only, to the accompanying diagrammatic Figures, in which:

FIG. 1 schematically depicts the effect of increased electrical conductivity and diminished optical transmission progressing from:
i) a single SrNbO₃ film of thickness t and region of charge transfer of thickness t_{CT} at the interface with the SrTiO₃ substrate;
ii) A SrNbO₃ film of thickness t, a SrTi₁₋ₓNbₓO₃ interface layer of thickness t_{Int} and fixed Nb content, x and a region of charge transfer of thickness t_{CT} at the interface with the SrTiO₃ substrate;
iii) a SrNbO₃ film of thickness t with a graded interface of SrTi₁₋ₓNbₓO₃ of thickness t_{Int} and Nb content, 1≤x≤0, and a region of charge transfer of thickness t_{CT} at the interface with the SrTiO₃ substrate; and
iv) a SrT₁₋ₓNbₓO₃ film with a fixed Nb content, x and a sharp interface with the SrTiO₃ substrate.

FIG. 2A shows measured and simulated HAADF-STEM images indicating the graded interface of 3 unit cells thickness (orange rectangle). The simulated image is overlaid with the cation assignment at each bright spot, Sr in red, Ti in blue, Nb in green and oxygen in white. FIG. 2B shows average oxidation state of 20 nm and 80 nm (nominal thickness) SrNbO₃ films on SrTiO₃ (pink star) and DyScO₃ (orange square) substrates extracted from XANES with measured standards (black squares) and calculated linear trend of average oxidation state against absorption edge energy. FIG. 2C shows the measured carrier concentration of the SrNbO₃/SrTi₁₋ₓNbₓO₃/SrTiO₃ system (green open circles) as calculated with film thickness measured from XRR, t. Model (blue dashed line) showing the predicted carrier concentration with film thickness when considering an additional charge transfer thickness, t_{CT} of 10 nm. Theoretical carrier concentration of SrNbO₃ (black solid line). FIG. 2D shows HAADF-STEM intensity versus depth showing the compositional change across the graded layer. FIG. 2E shows carrier mobility as a function of temperature for a 17 nm SrNbO₃ film on SrTiO₃ (black open squares) and a 16 nm SrNbO₃ film on LSAT (black solid squares).

FIG. 3A is a graph of measured transmittance as a function of wavelength for four films; and FIG. 3B is a graph of Haacke figure of merit (FOM) as a function of film thickness for SNO on STO and CaNbO₃ on STO.

FIG. 4A is a graph of normalised intensity as a function of 2θ for 74 nm SNO on STO; FIG. 4B is a graph of intensity as a function of ω for 74 nm SNO on STO; FIG. 4C is a graph of intensity as a function of 2θ for SNO on STO (111). Film deposited on other substrate orientation (STO (111)) grows highly crystalline in same condition. Shows the similar low room temperature sheet resistance as films on STO (001). FIG. 4D is a graph of oxidation state as a function of energy for different films. Thick sample (74 nm) on STO and thick (80 nm) and thin (20 nm) samples on DSO show oxidation state close to 4+. Thinner (20 nm) sample on STO shows slightly increased oxidation state which could be interpreted as a small amount of Nb diffusion into the STO substrate at the interface.

FIG. 5 schematically depicts a film according to an exemplary embodiment.

FIG. 6 is a graph of carrier concentration as a function of temperature for SrNbO₃ films for a series of thicknesses (2 nm, 5 nm, 19 nm, 39 nm, 61 nm and 74 nm) on SrTiO₃ substrates.

FIG. 7 is a graph of carrier mobility as a function of temperature for SrNbO₃ films for a series of thicknesses (2 nm, 5 nm, 19 nm, 39 nm, 61 nm and 74 nm) on SrTiO₃ substrates.

### DETAILED DESCRIPTION OF THE DRAWINGS

Although these interfacial properties have been widely studied, they are difficult to harness into application. LAO/STO heterostructures are made with precise techniques, requiring specific substrate termination and an exact number of unit cells to observe the effect. This kind of carefully controlled growth is time-consuming, and specific substrate termination requires chemical etching, often with toxic acids such as HF. Moreover, the charge is localised at the interface in a few unit cells and difficult to access.

SrTiO₃ is a transparent semiconductor with a band gap of 3.2 eV and an extraordinarily high dielectric constant εᵣ≈300 at room temperature, to tens of thousands at low temperatures. Electronic conduction can be induced with chemical dopants such as substitution of La³⁺ for Sr²⁺, Nb⁵⁺ for Ti⁴⁺ or by reduction of SrTiO_{3-δ}, where each oxygen vacancy generates two doped electrons. Doped SrTiO₃ exhibits a high-mobility metallic state with a strongly temperature dependent resistivity. At 4K, the electron mobility can reach over 20,000 cm²V⁻¹s⁻¹, [Spinelli 2010] compared with conventional metals such as Au, Ag and Cu typically <100 cm²V⁻¹s⁻¹ and correlated metals such as Sr(Ca)VO₃ and Sr(Ca)MoO₃ between 2 and 20 cm²V⁻¹s⁻¹. [Zhang (2015) N Mat, Stoner (2019) Adv. Fun. Mat.] SrNbO₃ is a 4d¹ correlated metal oxide with a minimum reported sheet resistance of 7.30/□ (thickness dependent, [Park (2020) Comm. Phys 3:102]) and a plasma frequency reported between 1.65-1.98 eV [Wan (2017) Nat Comm 1-8, 9, Park (2020) Comm. Phys 3:102].

An abrupt interface between the correlated metal and semiconductor with a large difference in carrier concentration would generate an electrostatic barrier and prevent the injection of highly mobile carriers into the metal. To overcome this, a graded interfacial layer is formed between the metal and the semiconductor. This concept is employed in conventional semiconductor applications such as High Electron Mobility Transistors (HEMTs), where the semiconductors used have dissimilar band gaps. The band discontinuities across the interface can be modified to form a continuous level by grading the transition from one semiconductor to the other. In a traditional HEMT device, the diffusion of carriers leads to the accumulation of the electrons along the boundary, forming a 2D electron gas (2DEG). Applying this concept to the correlated metal-semiconductor junction, the graded interface created would allow access to the highly mobile carriers while the transparency is governed by the bulk of the heterostructure, i.e. the correlated metal.

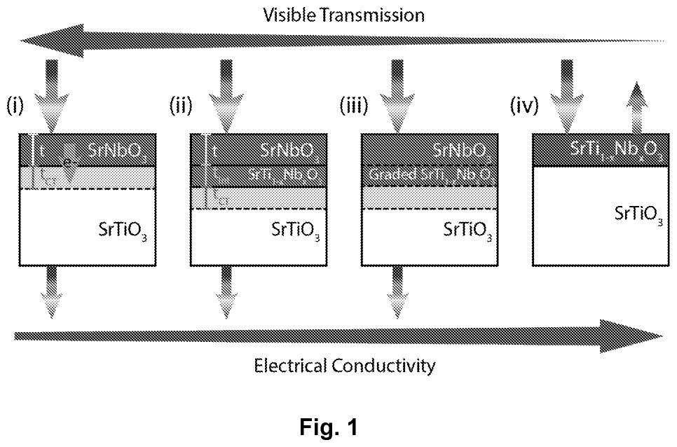

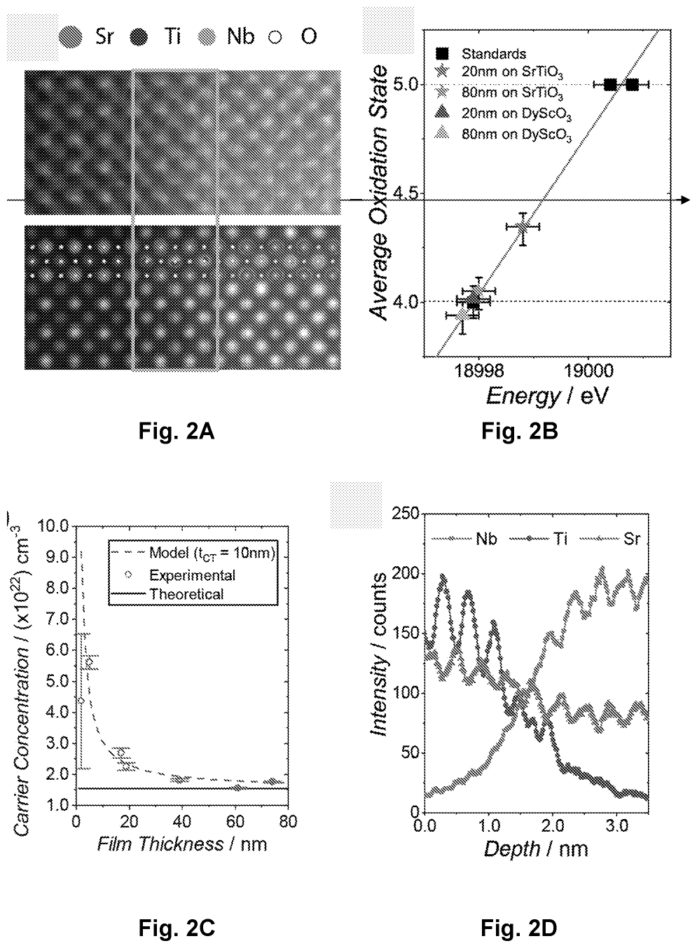

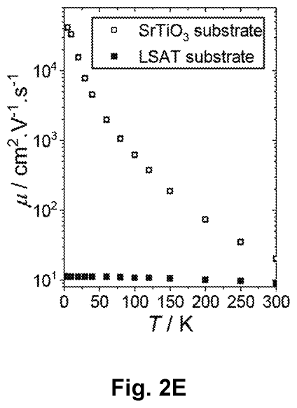

SrNbO₃ is a highly conducting, metallic oxide with cubic perovskite structure. Studies have previously shown its applications in photocatalysis and recently, it has been shown to be an effective transparent conductor in the visible and UV spectra, with a maximum figure of merit similar to other correlated metal TCOs. To create a graded correlated metal-semiconductor heterointerface, we have grown SrNbO₃ thin films over a series of thicknesses on SrTiO₃ substrates and studied their structural interface and, electrical and optical properties. The growth conditions allow for reduction of the SrTiO₃ substrate surface and niobium diffusion to create a graded interfacial layer with the SrNbO₃ film. Highly (0 0 1) oriented SrNbO₃ films have been obtained with an average root mean squared (RMS) surface roughness of 0.2 nm for a film thickness of 17 nm, up to a maximum of 0.9 nm for a film thickness of 132 nm (FIG. S5, Supporting Information). The lattice parameters for SrNbO₃ were calculated from reciprocal space mapping and out-of-plane diffraction with a=3.99(3) Å, b=4.01(3) Å in-plane and c=4.07(1) Å suggesting a small tetragonal distortion with c/a=1.02 Å. The in-plane lattice parameters are close to the reported value for bulk cubic SrNbO₃ with a_{bulk}=4.024 Å. The lattice mismatch between SrNbO₃ and SrTiO₃ is −2.96% and the rocking curve presents a broad Gaussian (FWHM 1.48(5)°) and narrow Lorentzian component (FWHM 0.074(1)°), which indicate the presence of dislocations in the films. High angle annular dark field scanning transmission electron microscopy (HAADF-STEM) images (FIG. 2A)) show the interfacial region were Ti and Nb cation intermixing occurs to create a gradual transition from correlated metal to semiconductor. Experimental and simulated intensity profiles (FIG. 2D) indicate cation grading over three atomic layers, approximately a thickness of 12.2 Å.

The average oxidation state of niobium in the film was determined from x-ray absorption near-edge spectroscopy (XANES) (FIG. 2B). The contribution of the interface region in the 80 nm sample has minimal effect on the average oxidation state to its small proportion of the whole system and is therefore saturated by the bulk SrNbO₃ properties. Films of nominal thicknesses 80 nm and 20 nm on DyScO₃ substrates, in which charge transfer or cation diffusion is not expected, show an average oxidation state of 3.94(9)+ and 4.01(9)+, within error on the nominal 4+. SrNbO₃ films of nominal thicknesses 80 nm and 20 nm on SrTiO₃ substrates were measured and show average oxidation states of +4.05(9) and +4.35(9) respectively. The intermixing of B-site cations at the interface alone is not enough to produce this magnitude of increased oxidation state. For an average increase of 0.35+, there would need to be a minimum diffusion interface thickness of 7 nm of Nb⁵⁺ (where x=1.0 in SrNbₓTi₁₋ₓO₃). From TEM there is only 1.22 nm of cation diffusion. It can also be assumed that surface oxidation and Nb⁵⁺ defects in the film would not cause a significant increase. Charge transfer in the 20 nm contributes significantly to the average oxidation state of the system, with approximately 35% Nb⁵⁺ resulting in electronically active Ti³⁺. This is consistent with the predicted charge transfer of Δnₑ=0.36 from Zhong and Hansmann.

FIG. 2C show the measured carrier concentration of SrNbO₃ films as a function of films thickness. The carrier concentration values are calculated using the film thickness measured using x-ray reflectivity, which does not consider the additional electronically active charge transfer region t_{CT} as indicated in FIG. 1 i) and ii). The seeming increase in carrier concentration is caused by the underestimation of the total electronically active thickness, t+t_{CT}, where t_{CT} is depth of the charge transfer into the SrTiO₃ substrate. In FIG. 2c, the model shows the change of carrier concentration with film thickness if an additional electronically active thickness t_{CT}=10 nm is accounted for.

Low effective mass observed explained from the band structure of STO doped with Nb: at high x(Nb) light electron dominate the transport

The room temperature resistivities of the SrNbO₃ films with thicknesses in the range of 2 to 74 nm on SrTiO₃ substrates, varied between 4.4(8) μΩcm and 12.8(4) μΩcm, more than an order of magnitude lower than the lowest reported value of 28.2 μΩcm for SrNbO₃ films on other substrates (Oka, Phys. Rev. B 92, 205102 (2015)). With decreasing film thickness, the room temperature resistivity tended to decrease. This is attributed to the electronically active charge transfer region, where the highly mobile, light carriers from the electron doped SrTiO₃ form a larger proportion of the whole system. The thinnest film of nominal thickness 2 nm shows a slight increase in resistivity, due to the film thickness being reduced below the electron mean free path (EMFP) of 3.5 nm and introducing surface scattering. [Park (2020) Comm. Phys 3:102].

At 2K, the resistivity in all films the resistivity decreases by three orders of magnitude, resulting in exceptionally large resistivity ratios (RRR>1000) compared to usual reported values for epitaxial perovskite films (<10), though similar to those reported for carrier doped SrTiO₃ (Spinelli et al. 2010). Our experimental results show a maximum (RRR)=ρ(300 K)/(2 K)=3122. SrNbO₃ films were also deposited on LSAT (0 0 1) and DyScO₃ (1 1 0) (DSO) substrates, where no charge transfer or Nb diffusion is expected. For a film thickness of 70 nm on DSO ρ(300 k)=49 μΩcm and on 16 nm on LSAT ρ(300 k)=70 μΩcm, within the same order of magnitude of the values previously reported. Transport results and further details are shown in Table 5.

TABLE 5
Electrical transport data for a series of thickness of SrNbO₃ films on SrTiO₃, DySCO₃
and LSAT substrates.

| | SrNbO₃ | | | | | |
|---|---|---|---|---|---|---|
| | Film | | | | | |
| | Thickness | p(300K) | p(2K) | | u(2K) | n(2K) |
| Substrate | (nm) | (μΩcm) | (μΩcm) | RRR | (cm²V⁻¹s⁻¹) | (×10²² cm⁻³) |
| SrTiO₃ (0 0 1) | 2 | 6.1 | 0.003 | 2015 | 47290 | 4.36 |
| | 5 | 4.4 | 0.002 | 2082 | 52700 | 5.62 |
| | 7 | 5.0 | 0.002 | 3123 | — | — |
| | 19 | 9.7 | 0.007 | 1463 | 41330 | 2.26 |
| | 39 | 12.8 | 0.009 | 1430 | 38290 | 1.82 |
| | 61 | 12.6 | 0.012 | 1012 | 32350 | 1.55 |
| | 74 | 11.3 | 0.008 | 1381 | 43400 | 1.75 |
| SrTiO₃ (1 1 1) | 23 | 14.6 | 0.007 | 2142 | 48340 | 2.01 |
| LSAT (0 0 1) | 16 | 69.8 | 61.7 | 1.13 | 11.3 | 0.89 |
| DyScO₃ (1 1 0) | 70 | 48.9 | 43.0 | 1.38 | * | * |

*The Hall resistance could not be measured due to the paramagnetic nature of DyScO₃.

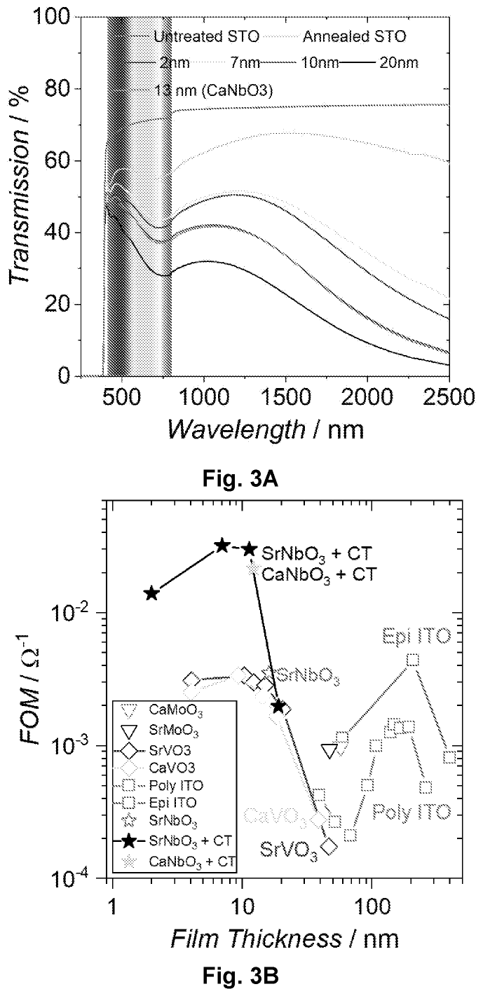

The transparent conductor's performance is assessed through the Haacke figure of merit, (FOM), φ_{TC}=T¹⁰/R, where T is the average transmission in the visible and Rₛ is the sheet resistance. The optical transmission was measured directly for of SrNbO₃ film thicknesses on double-side polished SMTO₃ substrates and the average transmission taken in the visible spectrum range of 400-800 nm. The highest achieved FOM for the SrNbO₃ and charge transfer system is 0.032 Ω⁻¹, significantly higher than SrNbO₃ and other correlated metals without the enhancement of charge transfer (FIG. 3B3, Table 6).

TABLE 6
TCM properties and FOM values for SrNbO₃ + charge
transfer systems with varying film thickness;
and for CaNbO³ on STO.

| SrNbO₃ Film | | Average | |
|---|---|---|---|
| Thickness | Rₛ | Transmission | FOM |
| (nm) | (Ω/□) | (400-800 nm) | (Ω⁻¹) |
| 2 | 9.9 | 0.82 | 0.014 |
| 7.2 | 6.9 | 0.86 | 0.032 |
| 11.3 | 2.1 | 0.76 | 0.03 |
| 19 | 5.1 | 0.63 | 0.00199 |
| 13 (CaNbO₃ on STO) | 3.6 | 0.76 | 0.019 |

Without the charge transfer between the correlated metal and transparent semiconductor, the enhanced transparent conducting properties could not be achieved.

Nb:doped STO has these highly mobile carriers, but at these thicknesses is not conducting enough to reach the desired sheet resistance. We can assume an average Nb dopant of 0.5 across our 3 unit cell interface, as the dopant is graded from 0 in the bulk SrTiO₃ to 1 in the bulk SrNbO₃. At 50% dopant, we only have on average around 1 E21 carriers. In this regime, for the desired sheet resistance of 10Ω/□, the film thickness must be over 800 nm and the average T in the visible is 0%. Therefore the diffusion of Nb into the STO cannot create these properties alone.

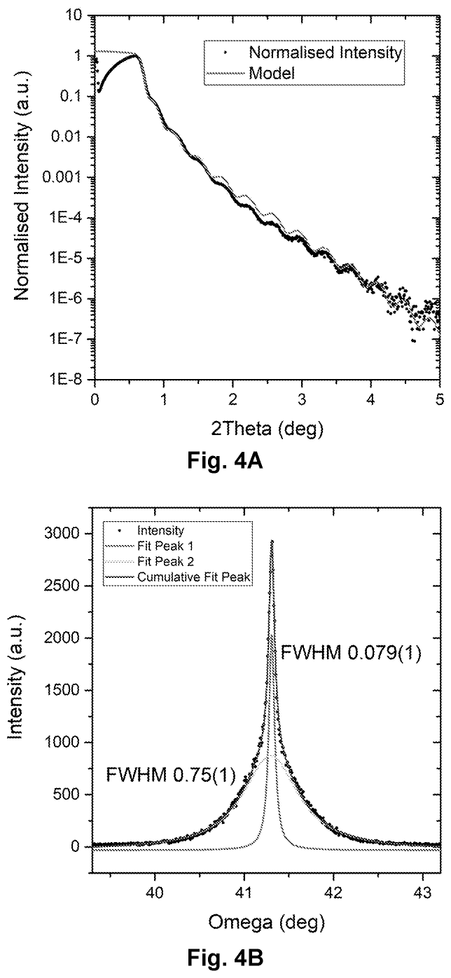

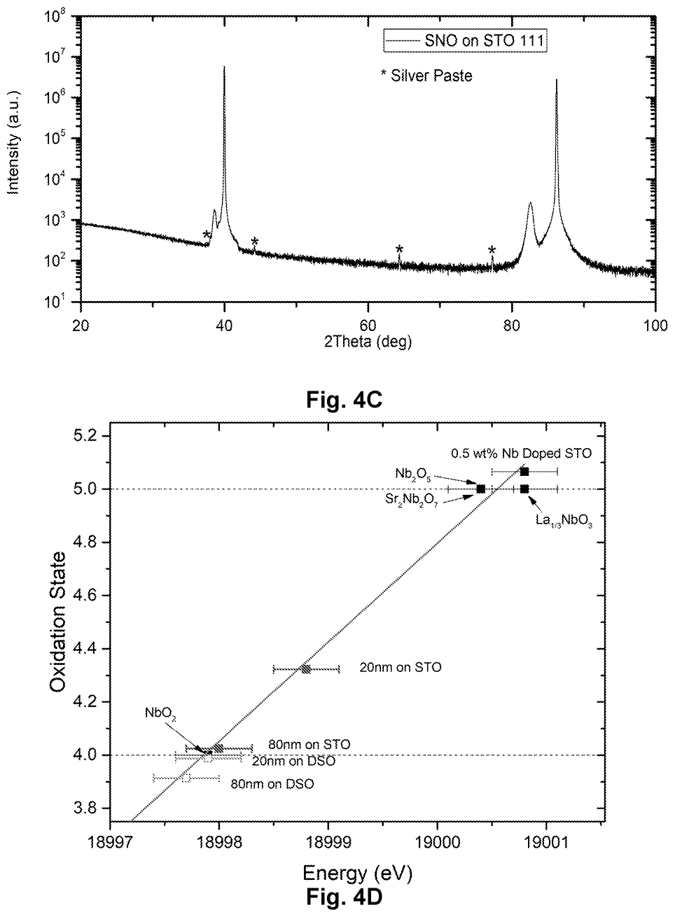

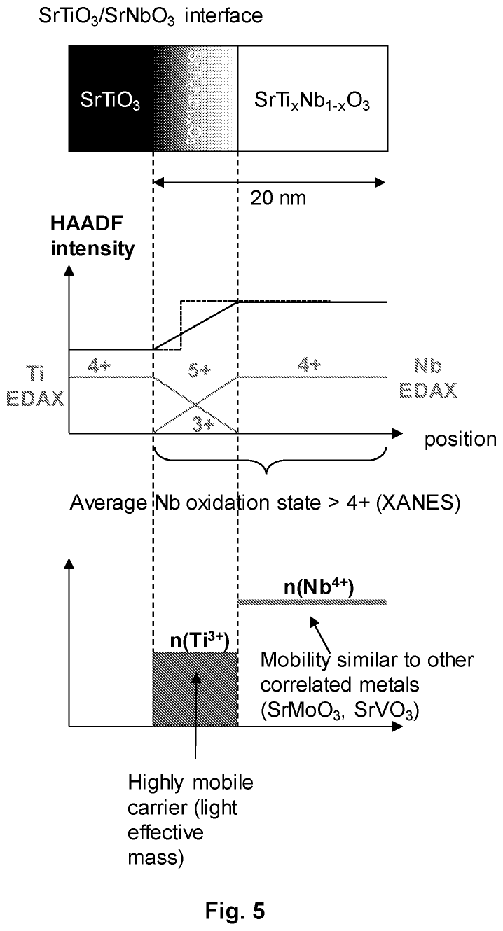

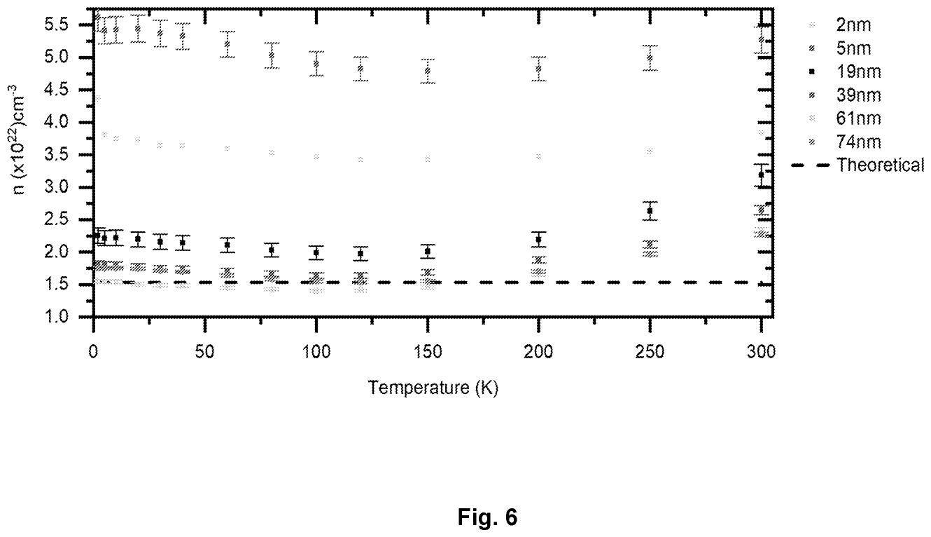

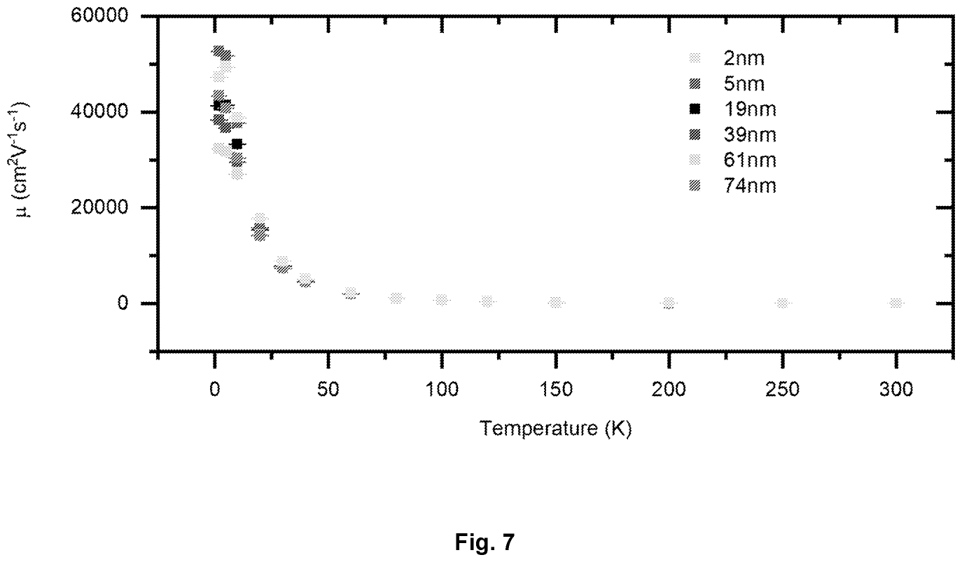

FIG. 4A is a graph of normalised intensity as a function of 2θ for 74 nm SNO on STO; FIG. 4B is a graph of intensity as a function of ω for 74 nm SNO on STO; FIG. 4C is a graph of intensity as a function of 2θ for SNO on STO (111); and FIG. 4D is a graph of oxidation state as a function of energy for different films. Thick sample (74 nm) on STO and thick (80 nm) and thin (20 nm) samples on DSO (DyScO₃ (110)) show oxidation state close to 4+. Thinner (20 nm) sample on STO shows slightly increased oxidation state which could be interpreted as a small amount of Nb diffusion into the STO substrate at the interface. Film deposited on other substrate orientation (STO (111)) grows highly crystalline in same condition. Shows the similar low room temperature sheet resistance as films on STO (001).

The diffraction data are for 20 nm SNO deposited on SrTiO₃ (111)—the films are of slightly higher crystal quality (indicated by the FWHM and peak shape of the rocking curve) than films deposited on STO (100) and importantly the high conductivity effect at room temperature still works when grown in this alternative orientation.

For the oxidation state data, the films on DSO for both thicknesses have an oxidation state of around 4+ which is the expected oxidation state for bulk SNO and it is thought that on DSO this relates to a single layer (i.e. no second or interface layer). On STO substrates (i.e. the third layer), the relatively thicker 80 nm SNO layer (i.e. the first layer) also has an oxidation state around 4+. This likely relates to two layers—the SNO first layer and the second or interface layer —but because the films is thick enough, a bulk oxidation state from the SNO layer is observed. A higher conductivity is observed than would be expected for a single layer of SNO even for the relatively thicker SNO film (80 nm). For the relatively thinner 20 nm SNO film on the STO substrate, a larger proportional effect from the interface layer is observed. This is due to Nb doping into the STO, forming the interface layer—so the oxidation state is a little higher, towards the Nb doped STO standard sample measured as oxidation state 5+ (top right black square point).

Experimental

Target Preparation and Film Growth

The SrNbO₃ films were deposited via pulsed laser deposition on SrTiO₃ (001), DyScO₃ (110), LaAlO₃ (001) and LSAT (001) single crystal substrates with lattice mismatch of −2.96%, −1.84%, −5.79% and −3.88% respectively. Substrates were sonicated in ethanol for cleaning but received no further treatment, retaining the mixed termination from manufacture.

A dense ceramic target of Sr₂Nb₂O₇ was prepared via conventional solid-state synthesis as outlined in the literature, with an additional pressing in a cold isostatic press before the final sintering step [Balasubramaniam, Journal of Solid State Chemistry, Volume 181, Issue 4, April 2008, pages 705-714].

The Nb⁵⁺ oxidation state of the target was reduced to the Nb⁴⁺ of the film during growth. This was achieved with a reducing growth environment as has been demonstrated in previous reports i.e. pulsed laser deposition in a low chamber base pressure (˜5×10−7 Torr), with no oxygen flow [Oka 2015]. The substrate was held at 750° C. throughout the growth. The laser fluence on the target was 0.74 J/cm² at a rate of 2 Hz with an KrF excimer laser.

XRD

The structural quality of the films was assessed with x-ray diffraction techniques using a Rigaku SmartLab diffractometer. A θ-2θ scan revealed the out-of-plane phase and crystallographic orientation. Wide reciprocal space mapping with a Hypix 2D detector was used to look for oxidized phases in plane.

AFM

AFM images were acquired using a Keysight 5600LS microscope in tapping mode.

TEM-EDX

TEM-EDX samples were prepared using focused ion beam (FIB) technique. The film was covered with carbon and platinum protection layers. For the high angle annular dark field scanning transmission electron microscopy (HAADF-STEM) imaging and STEM-EDX analysis, a probe aberration corrected microscope FEI Titian operated at 300 kV and equipped with Super X detector was used.

XANES

XANES measurements were taken on the B18 general purpose XAS beamline at Diamond Light Source. The Nb K-edge was measured on standards (NbO₂, Nb₂O₅, Sr₂Nb₂O₇, La_{1/3}NbO₃, 0.5 wt. % Nb doped STO) in transmission. The thin film samples and SrTiO₃ 0.05 wt % Nb doped single crystal were measured in grazing incidence geometry. Several measurements were taken for each sample and averaged to improve signal to noise ratio. The absorption edges were normalised in Athena data processing software.

UV-Vis A straight through baseline was taken with nothing in the beamline to account for environment effects. A SrTiO₃ substrate was annealed in growth conditions and measured to account for silver paste diffusion into the backside of the substrate. This was subtracted to measure the transmission of only the SrNbO₃ and charge transfer system without the interference of the substrate.

Transport

Transport property measurements were taken in a Quantum Design Physical Properties Measurement System (PPMS) capable of a temperature range of 300K to 2K and applying magnetic fields up to a magnitude of 14 T. The films were contacted in Van der Pauw geometry, which consists of four contacts in the corners of the samples.

Modelling—NextNano

Modelling of the Poisson solution of the SNO/STO interface was performed using NextNano (RTM) software package. The interface was modelled as 18 nm SrNbO₃ film with 1.2 nm interface thickness based on TEM results showing 3 unit cell interdiffusion of Nb/Ti. 18 nm film of SrNbO₃ is defined as SrTi₁₋ₓNbₓO₃ where x=1 and constant. Constant doping of 1.535×10²² cm⁻³ to define carrier density. 1.2 nm interface layer defined as SrTi₁₋ₓNbₓO₃ with linear gradation from x=1 to x=0. Dopants also defined as a linear gradation from 1.535×10²² cm⁻³ to 1×10¹⁶ cm⁻³ across the interface thickness. Substrate is SrTiO₃ with 1×10¹⁶ cm⁻³ n-type dopant (fully ionised) to account for reduction pre-film deposition.

Although a preferred embodiment has been shown and described, it will be appreciated by those skilled in the art that various changes and modifications might be made without departing from the scope of the invention, as defined in the appended claims and as described above.

### REFERENCES

Attention is directed to all papers and documents which are filed concurrently with or previous to this specification in connection with this application and which are open to public inspection with this specification, and the contents of all such papers and documents are incorporated herein by reference.

All of the features disclosed in this specification (including any accompanying claims and drawings), and/or all of the steps of any method or process so disclosed, may be combined in any combination, except combinations where at most some of such features and/or steps are mutually exclusive.

Each feature disclosed in this specification (including any accompanying claims, and drawings) may be replaced by alternative features serving the same, equivalent or similar purpose, unless expressly stated otherwise. Thus, unless expressly stated otherwise, each feature disclosed is one example only of a generic series of equivalent or similar features.

The invention is not restricted to the details of the foregoing embodiment(s). The invention extends to any novel one, or any novel combination, of the features disclosed in this specification (including any accompanying claims and drawings), or to any novel one, or any novel combination, of the steps of any method or process so disclosed.

1. A film comprising a set of layers including a first layer, a third layer and a second layer therebetween;
wherein the first layer comprises and/or is a transparent conductive oxide, TCO, having a formula:
A¹B¹O_{3-δ}_{₁};
wherein the third layer comprises and/or is a transparent wide-bandgap semiconductor oxide having a formula:
A³B³O_{3-δ3};
wherein the second layer comprises and/or is an oxide layer having a formula:
Aα¹A_{1-α}³B¹O_{3-δ}_{₂} or A_{α}¹A_{1-α}³B³O_{3-δ}_{₂} or A³Bβ¹B_{1-β}³O_{3-β}_{₂} or Aα¹A_{1-α}³B_{β}¹B_{1-β}³O_{3-β}_{₂};
wherein 0<α, β<1, −0.5≤δ₁, δ₂, δ₃≤0.5.

2. The film according to claim 1, wherein the first layer has the formula:
$${A}_{1 - x}^{1 , 1} {A}_{x}^{1 , 2} {B}_{1 - y}^{1 , 1} {B}_{y}^{1 , 2} {0}_{3 - {δ}_{1}} or {( {A}^{1 , 1} {B}^{1 , 1} {O}_{3 - {δ}_{1 , 1}} )}_{j} {( {A}^{1 , 2} {B}^{1 , 2} {O}_{3 - {δ}_{1 , 2}} )}_{k} ;$$
wherein 0<x, y<1, −0.5≤δ₁, (δ_{1,1}+δ_{1,2})≤0.5 and/or 1≤j, k≤10.

3. The film according to claim 1, wherein A¹ is selected from Group 2 (Be, Mg, Ca, Sr, Ba, Ra; preferably Ca, Sr, Ba) and/or the Lanthanides (La, Ce, Pr, Nd, Pm, Sm, Eu, Gd, Tb, Dy, Ho, Er, Tm, Yb, Lu; preferably La, Pr, Nd).

4. The film according to claim 1, wherein B¹ is selected from Group 5 (V, Nb, Ta, db; preferably V, Nb, Ta), Group 6 (Cr, Mo, W, Sg; preferably Cr, Mo, W) and/or Group 10 (Ni, Pd, Pt, Ds; preferably Ni).

5. The film according to claim 1, wherein the first layer has an electron mobility in a range from 1 to 100 cm²V⁻¹s⁻¹, a carrier density in a range from 1×10²⁰ to 1×10²⁴ cm⁻³, a transmittance in a range from 75% to 100% at a wavelength of 550 nm, a thickness in a range from 2 to 100 nm, an effective mass in a range from 1 to 10 m₀ and/or a conductivity in a range from 1,000 to 100,000 Scm⁻¹ at room temperature.

6. The film according to claim 1, wherein A³ and/or B³ is selected for adjusting a Fermi level position in a conduction band of the TCO of the first layer.

7. The film according to claim 1, wherein the transparent wide-bandgap semiconductor oxide has the formula:
$${A}_{1 - u}^{3 , 1} {A}_{u}^{3 , 2} {B}_{1 - v}^{3 , 1} {B}_{v}^{3 , 2} {0}_{3 - {δ}_{3}} or {( {A}^{3 , 1} {B}^{3 , 1} {O}_{3 - {δ}_{3 , 1}} )}_{m} {( {A}^{3 , 2} {B}^{3 , 2} {O}_{3 - {δ}_{3 , 2}} )}_{n} ;$$
wherein 0<u, v<1, −0.5≤δ₃, (δ_{3,1}+δ_{3,2})≤0.5 and/or 1≤m, n≤10.

8. The film according to claim 1, wherein A³ is selected from Group 2 (Be, Mg, Ca, Sr, Ba, Ra; preferably Ca, Sr, Ba), Group 12 (Zn, Cd, Hg, Cn; preferably Zn, Cd) and/or the Lanthanides (La, Ce, Pr, Nd, Pm, Sm, Eu, Gd, Tb, Dy, Ho, Er, Tm, Yb, Lu; preferably La, Pr, Nd).

9. The film according to claim 1, wherein B³ is selected from Group 4 (Ti, Zr, Hf, Rf; preferably Ti) and/or Group 14 (C, Si, Ge, Sn, Pb, UUq; preferably Sn).

10. The film according to claim 1, wherein the second layer comprises and/or is a compositionally-graded layer, optionally having a linear composition gradient therethrough.

11. The film according to claim 1, wherein the second layer has an electron mobility in a range from 1 to 100 cm²V⁻¹s⁻¹, a carrier density in a range from 1×10²⁰ to 1×10²⁴ cm⁻³, a transmittance in a range from 75% to 100% at a wavelength of 550 nm, a thickness in a ranged from 0.5 to 5 nm, an effective mass in a range from 1 to 10 m₀ and/or a conductivity in a range from 1,000 to 100,000 Scm⁻¹ at room temperature.

12. The film according to claim 1, wherein the TCO is SrNbO₃ and the transparent wide-bandgap semiconductor is SrTiO₃ or wherein the TCO is CaNbO₃ and the transparent wide-bandgap semiconductor is SrTiO₃ or wherein the TCO is LaNiO₃ and the transparent wide-bandgap semiconductor is BaSnO₃.

13. An electrode comprising a film according to claim 1 on a substrate.

14. A method of providing a film according to claim 1, comprising:
depositing the first layer on the third layer, for example by pulsed laser deposition.

15. The method according to claim 14, comprising diffusing at least some of B¹ into the third layer, thereby providing the second layer.
